(19) United States
(12) Patent Application Publication
(10) Pub. No.: US 2009/0090944 A1
(43) Pub. Date: Apr. 9, 2009

(54) Image Sensor and Method of Fabricating the Same

(76) Inventor: Dong Bin Park, Jayang-dong (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/234,973

(22) Filed: Sep. 22, 2008

(30) Foreign Application Priority Data
Oct. 4, 2007 (KR) 10-2007-0099613

(51) Int. Cl. H01L 31/00; H01L 21/00

(52) U.S. Cl. 257/292; 438/70; 257/E31.001; 257/E21.001

(57) ABSTRACT

Provided is an image sensor and a method of fabricating the image sensor. The image sensor can comprise: a semiconductor substrate comprising a photodiode; a metal wiring layer disposed on the semiconductor substrate and comprising a metal wiring and an interlayer dielectric; a trench formed in the interlayer dielectric to correspond to the photodiode; and a color filter formed in the trench. Accordingly, the distance between the photodiode and the color filter can be significantly reduced by forming the color filter in the trench.

### CROSS-REFERENCE TO RELATED APPLICATION

The present application claims the benefit under 35 U.S.C. §119 of Korean Patent Application No. 10-2007-0099613, filed Oct. 4, 2007, which is hereby incorporated by reference in its entirety.

### BACKGROUND

An image sensor is a semiconductor device for converting an optical image into an electrical signal. An image sensor is typically classified as a charge coupled device (CCD) image sensor or a complementary metal oxide semiconductor (CMOS) image sensor (CIS).

The CIS includes a photodiode and a metal oxide semiconductor (MOS) transistor in each unit pixel, and sequentially detects electrical signals of each unit pixel through a switching method to display an image.

A typical CIS includes a pixel array, an interlayer dielectric, a color filer, and a microlens. The pixel array includes the transistor and photodiode for each unit pixel, and the interlayer dielectric includes a plurality of wirings for the pixel array.

As a design rule is gradually reduced in these CMOS image sensors, the size of a unit pixel is decreased, thereby reducing photosensitivity of a photodiode.

Additionally, because the interlayer dielectric is formed of a plurality of layers, diffuse reflection of an incident light may occur. Thus, the incident light may be incident to a photodiode adjacent the intended photodiode, causing cross talk and noise.

### BRIEF SUMMARY

Embodiments of the present invention provide an image sensor capable of reducing an optical path of an incident light and a method of fabricating the same.

In one embodiment, an image sensor can comprise: a semiconductor substrate comprising a photodiode; a metal wiring layer disposed on the semiconductor substrate and comprising a metal wiring and an interlayer dielectric; a trench formed in the interlayer dielectric to correspond to the photodiode; and a color filter formed in the trench. A dielectric can be provided on the color filter to fill the trench. In addition, a microlens can be disposed on the dielectric above the color filter.

In another embodiment, a method of fabricating an image sensor can comprise: forming a photodiode on a semiconductor substrate; forming a metal wiring layer on the semiconductor substrate, the metal wiring layer comprising a metal wiring and an interlayer dielectric; forming a trench in the interlayer dielectric to correspond to the photodiode; and forming a color filter in the trench.

The details of one or more embodiments are set forth in the accompanying drawings and the description below. Other features will be apparent from the description and drawings, and from the claims.

### BRIEF DESCRIPTION OF THE DRAWINGS

FIGS. 1 to 6 are cross-sectional views illustrating a method of fabricating an image sensor according to an embodiment.

### DETAILED DESCRIPTION

An image sensor and a method of fabricating the same according to an embodiment will be described in detail with reference to the accompanying drawings.

It is to be understood that the figures and descriptions of embodiments of the present invention have been simplified to illustrate elements that are relevant for a clear understanding of the invention, while eliminating, for purposes of clarity, other elements that may be well known. Those of ordinary skill in the art will recognize that other elements may be desirable and/or required in order to implement the present invention. However, because such elements are well known in the art, and because they do not facilitate a better understanding of the present invention, a discussion of such elements is not provided herein.

FIG. 6 is a cross-sectional view of an image sensor according to an embodiment.

Referring to FIG. 6, an image sensor can include a semiconductor substrate 10 including a photodiode 30, a metal wiring layer disposed on the semiconductor substrate 10 and including a metal wiring 50 and an interlayer dielectric 40, a trench 65 formed in the interlayer dielectric 40 to correspond to the photodiode 30, and a color filter 70 formed in the trench 65.

The metal wiring layer can include a plurality of layers. That is, the interlayer dielectric 40 can be formed of a plurality of layers, and also the metal wiring 50 penetrating through the interlayer dielectric 40 can include a plurality of layers (e.g., M1, M2, and M3). For example, the interlayer dielectric 40 can be formed of one or more oxide layers and/or nitride layers. Additionally, the metal wiring 50 can be formed of any suitable conductive material known in the art (e.g., aluminum, copper, cobalt, or tungsten) including a metal, an alloy, or silicide.

The metal wiring 50 can be arranged in the interlayer dielectric 40 so as not to block light incident to the photodiode 30. Accordingly, the interlayer dielectric 40 can be disposed on the photodiode 30.

The trench 65 is formed in the interlayer dielectric 40 and formed at a position corresponding to the photodiode 30. In one embodiment, the trench 65 can be formed to expose the semiconductor substrate 10. In another embodiment, the trench 65 can be formed to expose a portion of the interlayer dielectric 40 having the lowest metal wiring M1 among the metal wirings 50. In a particular embodiment, the trench 65 can be formed lower than the portion of the interlayer dielectric 40 having the lowest metal wiring M1 while maintaining a depth that does not damage the surface of the photodiode 30.

The color filter 70 can be disposed in the trench 65. The color filter 70 can be formed for each unit pixel through the trench 65 formed on the photodiode 30 in order to separate colors from an incident light. For example, the color filter 70 may be one of a red, green, and blue color filter.

A dielectric 80 can be formed in the trench 80 including on the color filter 70. The dielectric 80 can be formed by filling the inside of the trench 65 with an insulating material when a gap remains between the trench 65 having the color filter 70 and a top surface of the interlayer dielectric 40. The dielectric 80 can be formed of a material having a low refractive index or reflectivity. For example, the dielectric 80 can be formed by filling the inside of the trench 65 with an oxide layer or a photosensitive material.

A microlens 90 can be disposed on the dielectric 80 corresponding to the color filter 70.

As mentioned above, the color filter 70 is formed in the trench 65 to reduce an optical path to the maximum between the photodiode 30 and the color filter 70 such that image characteristics can be improved.

Additionally, the color filter 70 can be disposed to be close to the photodiode 30 such that cross talk can be reduced.

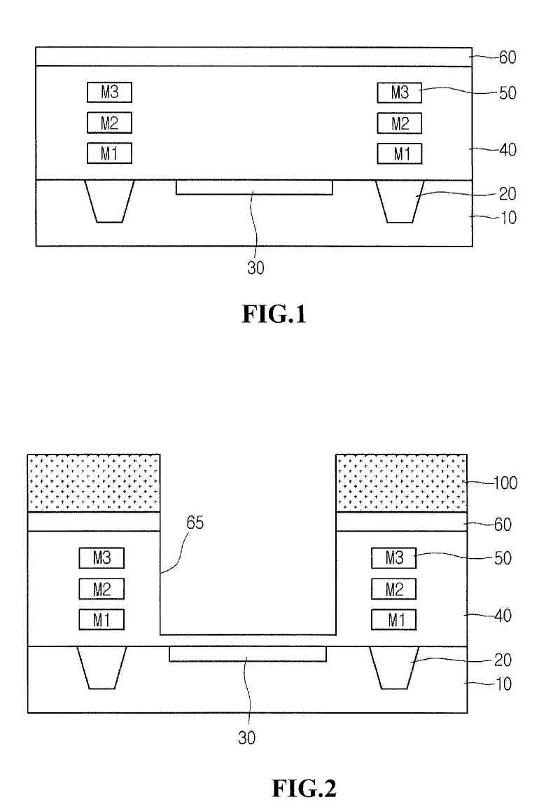

A method of fabricating an image sensor according to an embodiment will be described with reference to FIGS. 1 to 6.

Referring to FIG. 1, a metal wiring layer can be formed on a semiconductor substrate 10 having unit pixels defined thereon.

Although not illustrated, a device isolation region 20 can be formed in the semiconductor substrate 10 to define an active region and a field region. A unit pixel including a photodiode and a CMOS circuit can be formed on the active region.

The unit pixel can include a photodiode 30 receiving light to generate an optical charge and a CMOS circuit (not shown) connected to the photodiode 30 to convert the received photocharge into an electrical signal.

After forming related devices including the photodiode 30, the metal wiring layer including the interlayer dielectric 40 and metal wirings M1, M2, and M3 can be formed on the semiconductor substrate 10. The interlayer dielectric 40 can be formed of a plurality of layers, and the metal wiring 50 can be formed of a plurality of layers.

The metal wiring 50 can be formed in plurality and can be used to connect a power line and a signal line with a unit pixel and a peripheral circuit. The metal wiring 50 can be intentionally arranged so as not to block light incident to the photodiode 30. Accordingly, an interlayer dielectric 40 is disposed above the photodiode 30.

In certain embodiments, the interlayer dielectric 40 can be formed of one or more oxide layers and/or nitride layers. Additionally, the metal wiring 50 can be formed of any suitable conductive materials known in the art (e.g., aluminum, copper, cobalt, or tungsten) including a metal, an ally, or silicide.

After forming the final metal wiring M3 among the metal wirings 50, a hard mask layer 60 can be formed on the interlayer dielectric 40. The hard mask layer 60 can serve as an etching mask when a trench is formed in the interlayer dielectric 40 during a subsequent process. For example, the hard mask layer 60 can be formed of an oxide layer or a nitride layer. Of course, the hard mask layer 60 may be omitted.

Referring to FIG. 2, a trench 65 can be formed in the interlayer dielectric 40.

In one embodiment, a photoresist pattern 100 can be formed on the hard mask layer 60 to expose the surface of the hard mask layer 60 corresponding to the top area of the photodiode 30.

Then, the hard mask layer 60 and the interlayer dielectric 40 can be etched by using the photoresist pattern 100 as an etching mask to form the trench 65. The trench 65 can be formed through a wet or dry etching process. At this point, the bottom surface of the trench 65 can have a first depth that does not expose the photodiode 30. In one embodiment, the bottom surface of the trench 65 can expose the surface of the semiconductor substrate 10 while avoiding damage to the photodiode 30. In another embodiment, the bottom surface of the trench 65 can expose the bottom region of the interlayer dielectric 40 having the metal wiring M1 in order to not expose the photodiode 30.

Thereafter, the photoresist pattern 100 and the hard mask layer 60 can be removed.

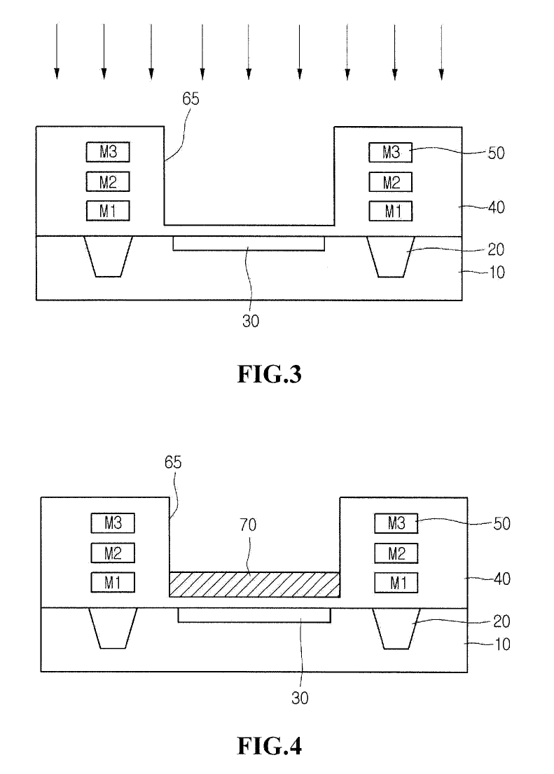

Referring to FIG. 3, a heat treatment process and a surface treatment process can be performed with respect to the trench 65. The heat treatment process can be performed to reduce surface damage of the trench 65 caused by the etching process.

Furthermore, the surface treatment process can be performed to change the inside surface of the trench 65 to be hydrophobic such that a color filter can be easily formed in the trench 65 during a subsequent process. For example, in one embodiment, the surface treatment process can be performed by coating an organic material on surfaces of the trench.

Referring to FIG. 4, a color filter 70 can be formed in the trench 65. The color filter 70 can be formed on the semiconductor substrate 10 through a spin coating process. The spin coating process utilizes a color filter material (not shown) including a photosensitive material and pigment or a photosensitive material and dyes. Next, the color filter material is exposed to light by a pattern mask (not shown) and developed in order to form the color filter 70 only inside the trench 65.

The color filter 70 can be disposed in the trench 65. The color filter 70 can be formed at each unit pixel through the trench 65 formed on the photodiode 30 in order to separate colors from an incident light. For example, the color filter 70 may be one of a red, green, and blue color filter.

As mentioned above, the color filter 70 can be formed in the trench 65 to reduce an optical path to the maximum between the photodiode 30 and the color filter 70 such that image characteristics can be improved.

Additionally, the color filter 70 can be formed on the photodiode 30 to inhibit light from being incident to an adjacent unit pixel such that cross talk and noise can be reduced.

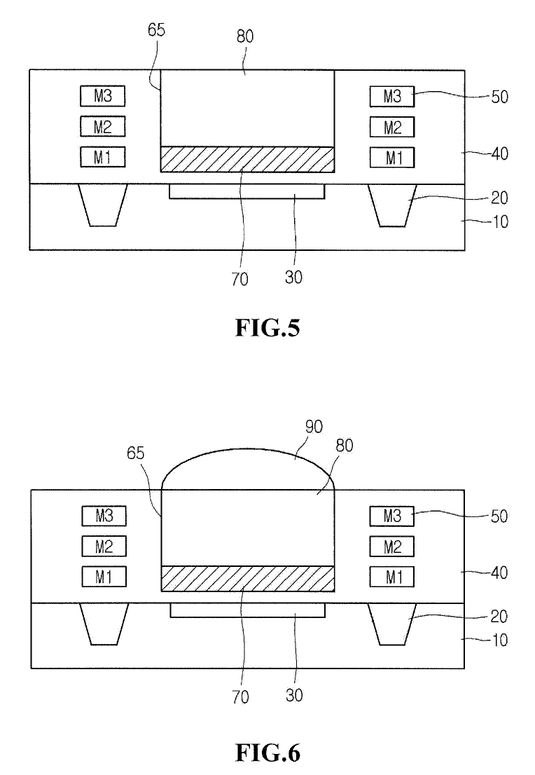

Referring to FIG. 5, a dielectric 80 can be formed in the trench 65 having the color filter 70. The dielectric 80 can be formed to fill the trench 65 when there is a gap between the color filter 70 and a top surface of the interlayer dielectric 40.

The dielectric 80 can be formed by gap-filling the semiconductor substrate 10 with a transparent material and then performing a planarization process. For example, the dielectric 80 can be formed of an oxide layer or a photosensitive material.

Referring to FIG. 6, a microlens 90 can be formed on the dielectric 80. A photosensitive photoresist or a silicon oxide layer series having a high transmittance can be used to form the microlens 90. In one embodiment, a photoresist can be coated and then patterned to form a microlens pattern corresponding to each unit pixel. Then, a reflow process can be performed to form a microlens 90 of a dome shape. Additionally, the microlens can be formed of a low temperature oxide layer.

The microlens 90 can be formed on the dielectric 80 above the color filter 70 to collect light into the photodiode 30.

In the method of fabricating an image sensor according to an embodiment, a color filter 70 can be formed inside the trench 65 within the interlayer dielectric 40 to be close to the photodiode 30 formed in the semiconductor substrate 10. Accordingly, because the distance between the photodiode 30 and the color filter 70 can be significantly reduced, the light transmitted through the color filter 70 can be directly incident to the photodiode 30.

Furthermore, the color filter 70 is formed close to the interface of the photodiode 30 such that cross talk can be reduced.

Moreover, because the distance between the color filter 70 and the photodiode 30 is reduced, refraction and reflection can be significantly reduced. Therefore, image characteristics of the image sensor can be improved.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a semiconductor substrate comprising a photodiode;
a metal wiring layer disposed on the semiconductor substrate, the metal wiring layer comprising a metal wiring and an interlayer dielectric;
a trench formed in the interlayer dielectric to correspond to the photodiode; and
a color filter formed in the trench.

2. The image sensor according to claim 1, wherein the metal wiring layer comprises a plurality of layers.

3. The image sensor according to claim 2, wherein the metal wiring layer comprises a first metal interconnection layer, a second metal interconnection layer on the first metal interconnection layer, and a third metal interconnection layer on the second metal interconnection layer.

4. The image sensor according to claim 3, wherein the trench extends below the first metal interconnection layer.

5. The image sensor according to claim 3, wherein a top surface of the color filter layer is below a height of the third metal interconnection layer.

6. The image sensor according to claim 1, further comprising a dielectric on the color filter and filling the trench.

7. The image sensor according to claim 1, further comprising a microlens disposed on the color filter.

8. The image sensor according to claim 1, wherein the trench exposes the semiconductor substrate corresponding to the photodiode.

9. A method of fabricating an image sensor, the method comprising:
forming a photodiode on a semiconductor substrate;
forming a metal wiring layer on the semiconductor substrate, the metal wiring layer comprising a metal wiring and an interlayer dielectric;
forming a trench in the interlayer dielectric to in a region corresponding to the photodiode; and
forming a color filter in the trench.

10. The method according to claim 9, wherein the metal wiring layer comprises a plurality of layers.

11. The method according to claim 9, wherein the forming of the trench comprises:
forming a photoresist pattern on the metal wiring to expose the interlayer dielectric corresponding to the photodiode; and
etching the interlayer dielectric by using the photoresist pattern as an etching mask.

12. The method according to claim 11, wherein a bottom of the trench is formed to expose the semiconductor substrate.

13. The method according to claim 11, wherein a bottom of the trench is formed to expose a lower layer of the interlayer dielectric.

14. The method according to claim 9, further comprising forming a dielectric on the color filter to fill the trench.

15. The method according to claim 9, further comprising forming a microlens on the color filter.

16. The method according to claim 9, further comprising performing a heat treatment process with respect to the trench to reduce damage to surfaces of the trench from the forming of the trench.

17. The method according to claim 9, further comprising performing a surface treatment with respect to the trench to provide a hydrophobic surface for the color filter.

18. The method according to claim 17, wherein performing the surface treatment comprises coating an organic material on surface of the trench before forming the color filter in the trench.
